(19) United States
(12) Patent Application Publication
(10) Pub. No.: US 2014/0045299 A1
(43) Pub. Date: Feb. 13, 2014

(54) FORMATION METHOD OF OXIDE SEMICONDUCTOR FILM

(71) Applicant: Semiconductor Energy Laboratory Co., Ltd., Atsugi-shi (JP)

(72) Inventor: Shunpei Yamazaki, Tokyo (JP)

(73) Assignee: Semiconductor Energy Laboratory Co., Ltd., Atsugi-shi (JP)

(21) Appl. No.: 13/957,746

(22) Filed: Aug. 2, 2013

(30) Foreign Application Priority Data
Aug. 10, 2012 (JP) 2012-178261

(51) Int. Cl. H01L 21/02

(52) U.S. Cl. CPC H01L 21/02595
USPC 438/104

(57) ABSTRACT

An oxide semiconductor film with high crystallinity is formed. An ion is made to collide with a sputtering target including a polycrystalline oxide containing a plurality of crystal grains to separate parts of the plurality of crystal grains and obtain flat plate-like sputtered particles, and the flat plate-like sputtered particles are deposited on a substrate having an insulating surface, which is heated at a temperature higher than 400° C. and lower than or equal to 500° C., to form an oxide semiconductor film including a crystal part over the substrate. Since the substrate which is a deposition surface is heated at a high temperature, the flat plate-like sputtered particles are rearranged and thus the oxide semiconductor film has a high film density.

### BACKGROUND OF THE INVENTION

1. Field of the Invention

The invention disclosed in this specification relates to a semiconductor device and a fabrication method thereof. The present invention particularly relates to an oxide semiconductor film included in a semiconductor device and a film formation method thereof.

Note that a semiconductor device in this specification and the like refers to any device which can function by utilizing semiconductor characteristics, and electro-optical devices, semiconductor circuits, and electronic devices are all semiconductor devices.

2. Description of the Related Art

A technique by which a transistor is formed using a semiconductor thin film formed over a substrate having an insulating surface has been attracting attention. The transistor is applied to a wide range of electronic devices such as an integrated circuit (IC) or an image display device (also simply referred to as a display device). As a semiconductor thin film applicable to the transistor, a silicon-based semiconductor material is widely known; moreover, an oxide semiconductor has been attracting attention as another material.

For example, Patent Document 1 discloses a transistor including an amorphous oxide semiconductor film containing In, Ga, and Zn and having an electron carrier concentration of lower than 10¹⁸/cm³, in which a sputtering method is considered the most suitable as a film formation method of the amorphous oxide semiconductor film.

Although a transistor including an oxide semiconductor film can obtain transistor characteristics relatively with ease, the oxide semiconductor film is likely to be amorphous and has unstable physical properties. Thus, it is difficult to secure reliability of such a transistor.

On the other hand, there is a report that a transistor including a crystalline oxide semiconductor film has more excellent electrical characteristics and higher reliability than a transistor including an amorphous oxide semiconductor film (see Non-Patent Document 1).

### REFERENCE

[Patent Document 1] Japanese Published Patent Application No. 2006-165528
[Non-Patent Document 1] Shunpei Yamazaki, Jun Koyama, Yoshitaka Yamamoto, and Kenji Okamoto, “Research, Development, and Application of Crystalline Oxide Semiconductor”, SID 2012 DIGEST, pp. 183-186

### SUMMARY OF THE INVENTION

An object is to provide a film formation method of an oxide semiconductor film with high crystallinity.

One embodiment of the disclosed invention is a method in which an oxide semiconductor film is formed by a sputtering method over a substrate heated at a temperature higher than 400° C. and lower than or equal to 500° C. with a sputtering target including a polycrystalline oxide containing a plurality of crystal grains.

Here, the plurality of crystal grains contained in the sputtering target has a plane that is cleaved or is likely to be cleaved because of a weak crystal bond (hereinafter simply referred to as a cleavage plane); therefore, the cleavage planes in the plurality of crystal grains are cleaved when an ion collides with the sputtering target, whereby flat plate-like sputtered particles can be obtained. The obtained flat plate-like sputtered particles are deposited on a substrate having a deposition surface; accordingly, an oxide semiconductor film is formed. The flat plate-like sputtered particle is formed by separation of part of the crystal grain and therefore has high crystallinity. Thus, an oxide semiconductor film with a high degree of crystallinity can be formed by depositing the sputtered particles. Further, since the substrate which is the deposition surface is heated at a high temperature (e.g., a temperature higher than 400° C. and lower than or equal to 500° C.), the flat plate-like sputtered particles are rearranged and thus the oxide semiconductor film can have a high film density.

More specifically, for example, the following film formation method can be employed.

According to one embodiment of the present invention, a method for forming an oxide semiconductor film includes the steps of making an ion collides with a sputtering target including a polycrystalline oxide containing a plurality of crystal grains to separate parts of the plurality of crystal grains and obtain flat plate-like sputtered particles, and depositing the flat plate-like sputtered particles on a substrate having an insulating surface, which is heated at a temperature higher than 400° C. and lower than or equal to 500° C., to form an oxide semiconductor film including a crystal part over the substrate.

In the above film formation method, it is preferable that the flat plate-like sputtered particle have a hexagonal prism shape, and a hexagonal plane of the hexagonal prism be parallel to an a-b plane of a crystal, and a direction perpendicular to the hexagonal plane be a c-axis direction of the crystal.

In addition, in the above film formation method, the flat plate-like sputtered particles are preferably deposited in a direction such that the hexagonal plane is parallel to a deposition surface of the substrate.

Further, in the above film formation method, in the flat plate-like sputtered particle, the length of a diagonal line of the hexagonal plane is preferably greater than or equal to 3 nm and less than or equal to 10 nm.

According to one embodiment of the present invention, an oxide semiconductor film with high crystallinity can be formed.

### BRIEF DESCRIPTION OF THE DRAWINGS

FIGS. 1A and 1B are schematic diagrams illustrating a state of film formation using a sputtering target.

FIGS. 2A and 2B are schematic diagrams illustrating a state of film formation using a sputtering target.

FIGS. 3A and 3B are diagrams illustrating an example of a crystal structure of an In—Ga—Zn oxide.

FIG. 4 is a diagram illustrating an example of a crystal structure of an In—Ga—Zn oxide.

FIG. 5 is a flow chart illustrating an example of a fabrication process of a sputtering target.

FIGS. 6A to 6C are a plan view and cross-sectional views illustrating a semiconductor device of one embodiment of the present invention.

FIGS. 7A to 7D are cross-sectional views illustrating an example of a fabrication method of a semiconductor device of one embodiment of the present invention.

FIGS. 8A to 8C are a plan view and cross-sectional views illustrating a semiconductor device of one embodiment of the present invention.

FIGS. 9A and 9B are each a circuit diagram of a semiconductor device of one embodiment of the present invention.

FIGS. 10A to 10C are circuit diagrams and a conceptual diagram of a semiconductor device of one embodiment of the present invention.

FIG. 11 is a block diagram of an electronic device of one embodiment of the present invention.

FIGS. 12A to 12D are each an external view of an electronic device of one embodiment of the present invention.

### DETAILED DESCRIPTION OF THE INVENTION

Embodiments of the present invention are described in detail below with reference to the accompanying drawings. However, the present invention is not limited to the description below, and it is easily understood by those skilled in the art that modes and details thereof can be modified in various ways. Therefore, the present invention is not construed as being limited to description of the embodiments.

Note that in each drawing described in this specification, the size, the film thickness, or the region of each component is in some cases exaggerated for clarity. Therefore, the embodiments of the present invention are not limited to such scales.

Note that the ordinal numbers such as “first” and “second in this specification and the like are used for convenience and do not indicate the order of steps or the stacking order of layers. In addition, the ordinal numbers in this specification and the like do not indicate particular names which specify the present invention.

In this specification, a term “parallel” indicates that the angle formed between two straight lines is greater than or equal to −10° and less than or equal to 10°, and accordingly also includes the case where the angle is greater than or equal to −5° and less than or equal to 5°. In addition, a term “perpendicular” indicates that the angle formed between two straight lines is greater than or equal to 80° and less than or equal to 100°, and accordingly includes the case where the angle is greater than or equal to 85° and less than or equal to 95°.

In this specification, the trigonal and rhombohedral crystal systems are included in the hexagonal crystal system.

### Embodiment 1

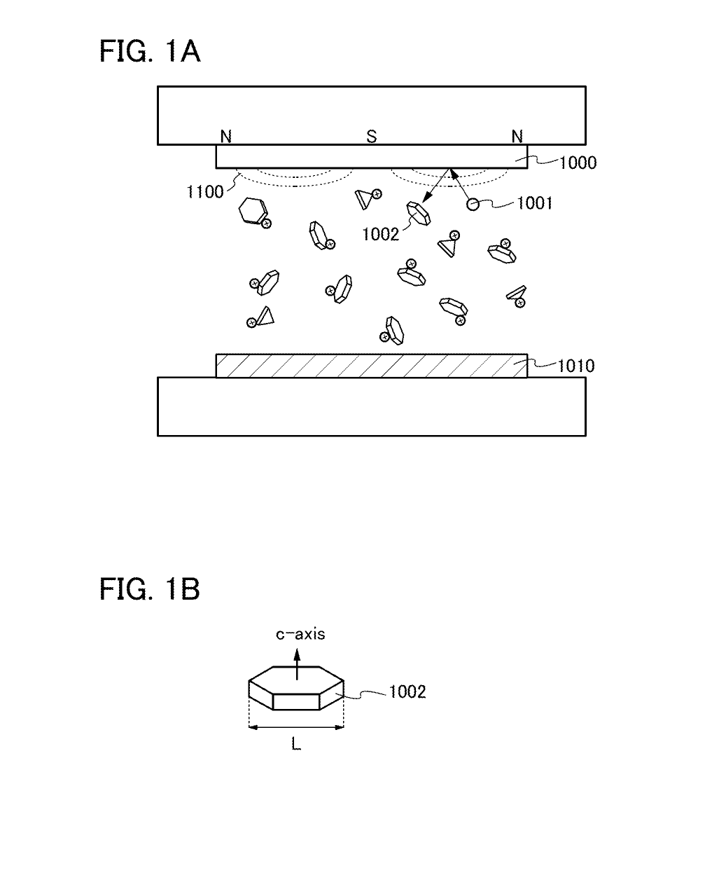

In this embodiment, a film formation method of an oxide semiconductor film of one embodiment of the present invention will be described with reference to FIGS. 1A and 1B, FIGS. 2A and 2B, FIGS. 3A and 3B, and FIG. 4.

FIG. 1A is a schematic diagram illustrating a state in which an ion 1001 collides with a sputtering target 1000 to separate crystalline sputtered particles 1002 from the sputtering target 1000 and the crystalline sputtered particles 1002 are transferred to a substrate 1010 having a deposition surface.

FIG. 1A illustrates the case of using a DC magnetron sputtering method, in which case a magnet is provided inside or outside a target support for supporting the sputtering target 1000. In this structure, a semi-circular magnetic force line 1100 is generated on the sputtering target 1000. With the magnet, high-density plasma can be confined in the periphery of the sputtering target 1000, so that improvement in deposition rate and a reduction in plasma damage to the substrate 1010 can be achieved. Note that N and S in FIG. 1A denote an N-pole and an S-pole of the magnet provided inside or outside the target support, and an N-pole and an S-pole may be substituted for each other.

The sputtering target 1000 includes a polycrystalline oxide containing a plurality of crystal grains. The crystal grain contained in the sputtering target 1000 includes a portion where an interatomic bond is weak, and the interatomic bond of the portion is cut when the ion 1001 collides with the portion of the crystal grain. Accordingly, the crystal grain is cleaved and the flat plate-like sputtered particle 1002 is separated.

Note that the sputtered particle 1002 may have a hexagonal prism shape and its cleavage plane may be parallel to an a-b plane of a crystal. In the case where the sputtered particle has a hexagonal prism shape, the direction perpendicular to the hexagonal plane is a c-axis direction of the crystal (see FIG. 1B). The diameter of a plane of the sputtered particle 1002, which is parallel to the a-b plane of the crystal, is preferably about greater than or equal to 3 nm and less than or equal to 10 nm. In the case where the sputtered particle has a hexagonal prism shape, the length of the diagonal line of a hexagonal plane (L in FIG. 1B) is preferably greater than or equal to 3 nm and less than or equal to 10 nm.

An oxygen cation is used as the ion 1001. In addition, a cation of a rare gas (e.g., argon) may be used in addition to the oxygen cation. With the use of the oxygen cation as the ion 1001, plasma damage at the film formation can be alleviated. Thus, when the ion 1001 collides with the surface of the sputtering target 1000, a deterioration in crystallinity of the sputtering target 1000 can be suppressed or a change of the sputtering target 1000 into an amorphous state can be suppressed.

It is preferable that the separated sputtered particles 1002 be positively charged. There is no particular limitation on a timing of when the sputtered particle 1002 is positively charged; it may be positively charged by receiving an electric charge when the ion 1001 collides, for example. Alternatively, in the case where plasma is generated, the sputtered particle 1002 may be exposed to plasma to be positively charged. Further alternatively, the ion 1001 which is an oxygen cation may be bonded to a surface of the sputtered particle 1002, whereby the sputtered particle 1002 is positively charged.

The sputtered particles 1002 are deposited on a substrate 1010 having a deposition surface; accordingly, an oxide semiconductor film is formed. Note that the substrate 1010 is heated at a temperature higher than 400° C. and lower than or equal to 500° C. When the temperature of the substrate 1010 having a deposition surface is high, the sputtered particles 1002 deposited on the substrate 1010 are rearranged; accordingly, a high-density oxide semiconductor film can be obtained. Note that it is possible to heat the substrate at a temperature higher than 500° C.; however, the substrate is preferably heated at a temperature lower than or equal to 500° C. in order to improve productivity.

Note that as the heating means of the substrate 1010, lamp heating by irradiation with a Xe lamp or the like is preferably performed in terms of the problem of impurity contamination, but other heating means may be employed as appropriate as long as the substrate can be heated at a temperature higher than 400° C. and lower than or equal to 500° C. For example, resistance heating or the like can be employed.

The atmosphere of film formation is preferably controlled so as to hardly contain hydrogen and moisture (i.e., an inert atmosphere, a reduced-pressure atmosphere, or a dry air atmosphere). For example, in terms of moisture, a preferable atmosphere is a dry nitrogen atmosphere in which the dew point of moisture is lower than or equal to −40° C., preferably lower than or equal to −50° C.

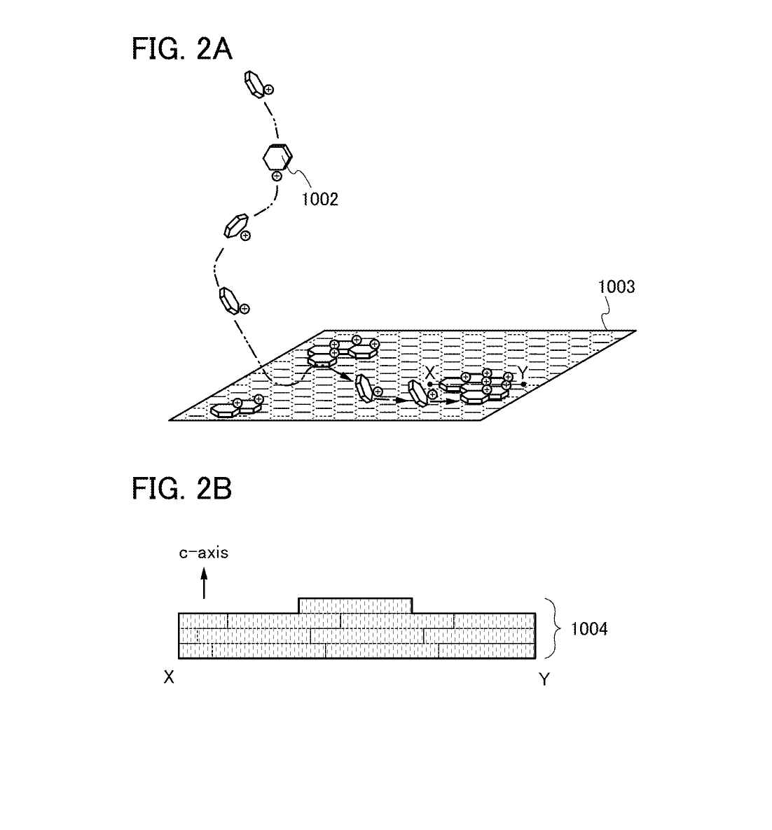

A state in which the sputtered particles 1002 are deposited on a deposition surface is described below with reference to FIGS. 2A and 2B. Note that in FIGS. 2A and 2B, sputtered particles which have been already deposited are shown by dotted lines.

In FIG. 2A, a deposition surface 1003 has a surface on which some layers of the sputtered particles 1002 are deposited. In the case of FIG. 2A where the sputtered particles 1002 are positively charged, the sputtered particles 1002 are deposited in a region of the deposition surface 1003, where no sputtered particle 1002 has been deposited yet. This is because the sputtered particles 1002 which are positively charged repel each other.

The substrate is heated at a temperature higher than 400° C. and lower than or equal to 500° C. As the substrate heating temperature at the time of film formation becomes higher, the impurity concentration of the obtained oxide semiconductor film can be reduced. Further, migration of the sputtered particles 1002 on the deposition surface 1003 becomes likely to occur or the migration length becomes longer as the substrate heating temperature at the time of film formation becomes higher; therefore, the atomic arrangement in the oxide semiconductor film is ordered and the density thereof is increased, so that an oxide semiconductor film with a high degree of crystallinity can be formed. For example, in the case where the sputtered particle 1002 has a hexagonal prism shape, the hexagonal prism sputtered particles 1002 are arranged with high density in such a manner that one side of a hexagon and one side of another hexagon adjacent thereto are in contact with each other by migration of the sputtered particles 1002 on the deposition surface 1003.

In the case of performing film formation using a magnetron sputtering method, force is applied to the sputtered particle 1002 by a magnetic field and current and thus the sputtered particle 1002 moves; accordingly, one side of a top surface of a hexagonal prism and one side of a top surface of another hexagonal prism adjacent thereto can be in contact with each other.

The film formation is preferably performed in an oxygen gas atmosphere. When the film formation is performed in an oxygen gas atmosphere, plasma damage is alleviated and a surplus atom such as a rare gas atom is not contained in the oxide semiconductor film, whereby an oxide semiconductor film with a high degree of crystallinity is likely to be formed. Note that the film formation may be performed in a mixed atmosphere including an oxygen gas and a rare gas. In that case, the percentage of an oxygen gas is higher than or equal to 30 vol. %, preferably higher than or equal to 50 vol. %, more preferably higher than or equal to 80 vol. %.

When the oxygen flow rate is high and the pressure inside a chamber is high during film formation, oxygen ions are attached to the flat plate-like sputtered particle, so that the flat plate-like sputtered particle can have much oxygen on its surface. Another flat plate-like sputtered particle is stacked thereover before the attached oxygen is released; thus, much oxygen can be contained in the film. The oxygen adsorbed on the surface contributes to a reduction in the number of oxygen vacancies in the oxide semiconductor.

FIG. 2B is a cross-sectional view taken along dashed-dotted line X-Y in FIG. 2A. The c-axes of crystals of the sputtered particles 1002 deposited in the above manner are aligned in a direction perpendicular to the deposition surface 1003; accordingly, an oxide semiconductor film 1004, which is formed, is a c-axis aligned crystalline oxide semiconductor (CAAC-OS) film.

The CAAC-OS film is one of oxide semiconductor films including a plurality of crystal parts, and most of the crystal parts each fit inside a cube whose one side is less than 100 nm. Thus, there is a case where a crystal part included in the CAAC-OS film fits inside a cube whose one side is less than 10 nm, less than 5 nm, or less than 3 nm. However, when the substrate heating temperature at the time of film formation is high, the size of the crystal part included in the CAAC-OS film becomes larger in some cases so as to exceed the above range. Further, when the substrate heating temperature at the time of film formation is high, an oxide semiconductor film with a high degree of crystallinity can be formed, and an oxide semiconductor film close to a single crystal is obtained in some cases.

The CAAC-OS film is described in detail below.

In a transmission electron microscope (TEM) image of the CAAC-OS film, a boundary between crystal parts, that is, a grain boundary is not clearly observed. Thus, in the CAAC-OS film, a reduction in electron mobility due to the grain boundary is less likely to occur.

According to the TEM image of the CAAC-OS film observed in a direction substantially parallel to a sample surface (cross-sectional TEM image), metal atoms are arranged in a layered manner in the crystal parts. Each metal atom layer has a morphology reflected by a surface over which the CAAC-OS film is formed (hereinafter, a surface over which the CAAC-OS film is formed is referred to as a formation surface) or a top surface of the CAAC-OS film, and is arranged in parallel to the formation surface or the top surface of the CAAC-OS film.

On the other hand, according to the TEM image of the CAAC-OS film observed in a direction substantially perpendicular to the sample surface (plan TEM image), metal atoms are arranged in a triangular or hexagonal configuration in the crystal parts. However, there is no regularity of arrangement of metal atoms between different crystal parts.

From the results of the cross-sectional TEM image and the plan TEM image, alignment is found in the crystal parts in the CAAC-OS film.

A CAAC-OS film is subjected to structural analysis with an X-ray diffraction (XRD) apparatus. For example, when the CAAC-OS film including an InGaZnO₄ crystal is analyzed by an out-of-plane method, a peak appears frequently when the diffraction angle (2θ) is around 31°. This peak is derived from the (009) plane of the InGaZnO₄ crystal, which indicates that crystals in the CAAC-OS film have c-axis alignment, and that the c-axes are aligned in a direction substantially perpendicular to the formation surface or the top surface of the CAAC-OS film.

On the other hand, when the CAAC-OS film is analyzed by an in-plane method in which an X-ray enters a sample in a direction substantially perpendicular to the c-axis, a peak appears frequently when 2θ is around 56°. This peak is derived from the (110) plane of the InGaZnO₄ crystal. Here, analysis (φ scan) is performed under conditions where the sample is rotated around a normal vector of a sample surface as an axis (φ axis) with 2θ fixed at around 56°. In the case where the sample is a single crystal oxide semiconductor film of InGaZnO₄, six peaks appear. The six peaks are derived from crystal planes equivalent to the (110) plane. On the other hand, in the case of a CAAC-OS film, a peak is not clearly observed even when 0 scan is performed with 2θ fixed at around 56°.

According to the above results, in the CAAC-OS film having c-axis alignment, while the directions of a-axes and b-axes are different between crystal parts, the c-axes are aligned in a direction parallel to a normal vector of a formation surface or a normal vector of a top surface. According to the above results, in the CAAC-OS film having c-axis alignment, while the directions of a-axes and b-axes are different between crystal parts, the c-axes are aligned in a direction parallel to a normal vector of a formation surface or a normal vector of a top surface. Thus, each metal atom layer arranged in a layered manner observed in the cross-sectional TEM image corresponds to a plane parallel to the a-b plane of the crystal.

Note that the crystal part is formed concurrently with film formation of the CAAC-OS film or is formed through crystallization treatment such as heat treatment. As described above, the c-axis of the crystal is aligned in a direction parallel to a normal vector of a formation surface or a normal vector of a top surface. Thus, for example, in the case where a shape of the CAAC-OS film is changed by etching or the like, the c-axis might not be necessarily parallel to a normal vector of a formation surface or a normal vector of a top surface of the CAAC-OS film.

Further, the degree of crystallinity in the CAAC-OS film is not necessarily uniform. For example, in the case where crystal growth leading to the CAAC-OS film occurs from the vicinity of the top surface of the film, the degree of the crystallinity in the vicinity of the top surface is in some cases higher than that in the vicinity of the formation surface. Further, when an impurity is added to the CAAC-OS film, the degree of crystallinity in a region to which the impurity is added is changed, and the degree of crystallinity in the CAAC-OS film varies depending on regions.

Note that when the CAAC-OS film with an InGaZnO₄ crystal is analyzed by an out-of-plane method, a peak of 2θ may also be observed at around 36°, in addition to the peak of 2θ at around 31°. The peak of 2θ at around 36° indicates that a crystal having no c-axis alignment is included in part of the CAAC-OS film. It is preferable that in the CAAC-OS film, a peak of 2θ appear at around 31° and a peak of 2θ do not appear at around 36°.

In a transistor using the CAAC-OS film, change in electric characteristics due to irradiation with visible light or ultraviolet light is small. Thus, the transistor has high reliability.

In the above manner, the oxide semiconductor film 1004 which is obtained by deposition has a uniform crystal orientation. The sputtered particles 1002 are not deposited randomly. The sputtered particles 1002 which are positively charged interact with each other and are deposited orderly so that c-axes are aligned in a direction perpendicular to the deposition surface 1003.

By film formation of an oxide semiconductor film with the above film formation method, an oxide semiconductor film with high crystallinity and a uniform crystal orientation can be formed.

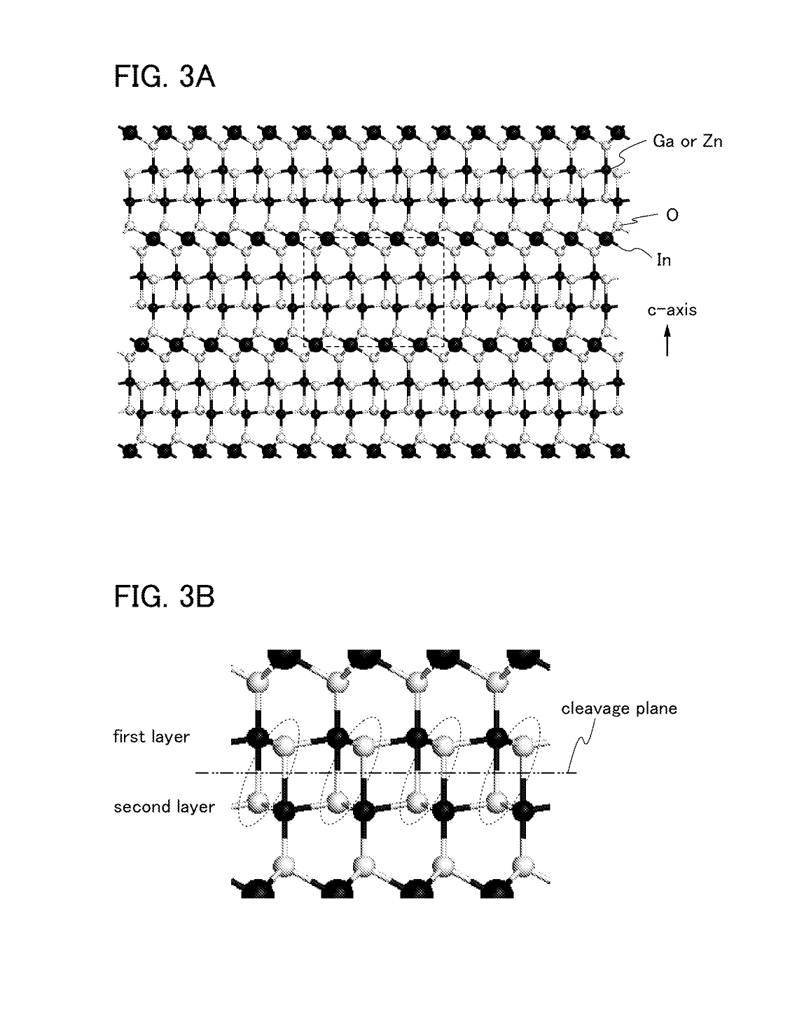

FIG. 3A illustrates an example of the crystal structure of an In—Ga—Zn oxide viewed from a direction parallel to the a-b plane. Further, FIG. 3B illustrates an enlarged portion surrounded by a dashed line in FIG. 3A.

For example, in a crystal grain of an In—Ga—Zn oxide, a cleavage plane is a plane between a first layer and a second layer as illustrated in FIG. 3B. The first layer includes at least one of a gallium atom and a zinc atom, and an oxygen atom, and the second layer includes at least one of a gallium atom and a zinc atom, and an oxygen atom. This is because oxygen atoms having negative charge in the first layer and oxygen atoms having negative charge in the second layer are close to each other (see a portion surrounded by a dotted line in FIG. 3B). Since the cleavage plane is a flat plane parallel to an a-b plane, the sputtered particle including an In—Ga—Zn oxide has a flat plate-like shape having a flat plane parallel to an a-b plane.

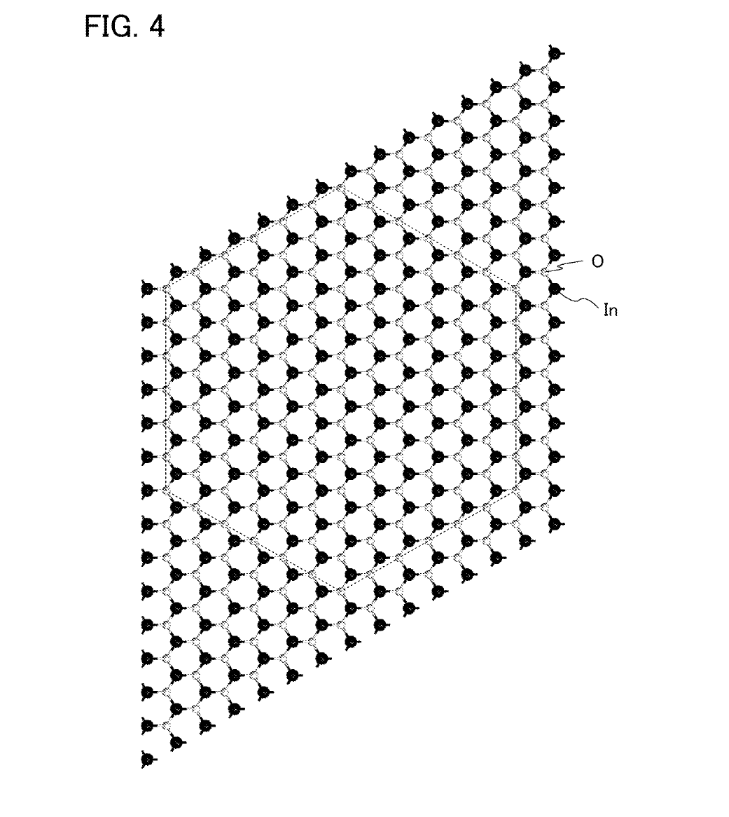

FIG. 4 illustrates an example of the crystal structure of an In—Ga—Zn oxide viewed from a direction perpendicular to the a-b plane of the crystal. Note that in FIG. 4, only a layer including indium atoms and oxygen atoms is extracted.

In the In—Ga—Zn oxide, a bond between an indium atom and an oxygen atom is weak and easily cut. When the bond is cut, the oxygen atom is detached, and vacancies of oxygen atoms (also referred to as oxygen vacancy) are sequentially caused as shown by a dotted line in FIG. 4. In FIG. 4, a regular hexagonal shape can be traced by connecting the oxygen vacancies by the dotted line. As described above, the crystal of the In—Ga—Zn oxide has a plurality of planes which are perpendicular to an a-b plane and generated when the bonds between indium atoms and oxygen atoms are cut.

The crystal of the In—Ga—Zn oxide is a hexagonal crystal; thus, the flat plate-like sputtered particle is likely to have a hexagonal prism shape with a regular hexagonal plane whose internal angle is 120°. Note that the flat plate-like sputtered particle is not limited to a hexagonal prism shape, and in some cases, it has a triangular prism shape with a regular triangular plane whose internal angle is 60° or a polygonal prism shape different from the above shapes.

The oxide semiconductor film described in this embodiment can be used for a channel region of a transistor. With the use of the oxide semiconductor film described in this embodiment for a channel region of a transistor, the transistor can have excellent electrical characteristics and high reliability. The oxide semiconductor film may also be used as a transparent conductive film.

The methods and structures described in this embodiment can be combined as appropriate with any of the methods and structures described in the other embodiments.

### Embodiment 2

In this embodiment, a sputtering target which can be used for forming an oxide semiconductor film of one embodiment of the present invention will be described.

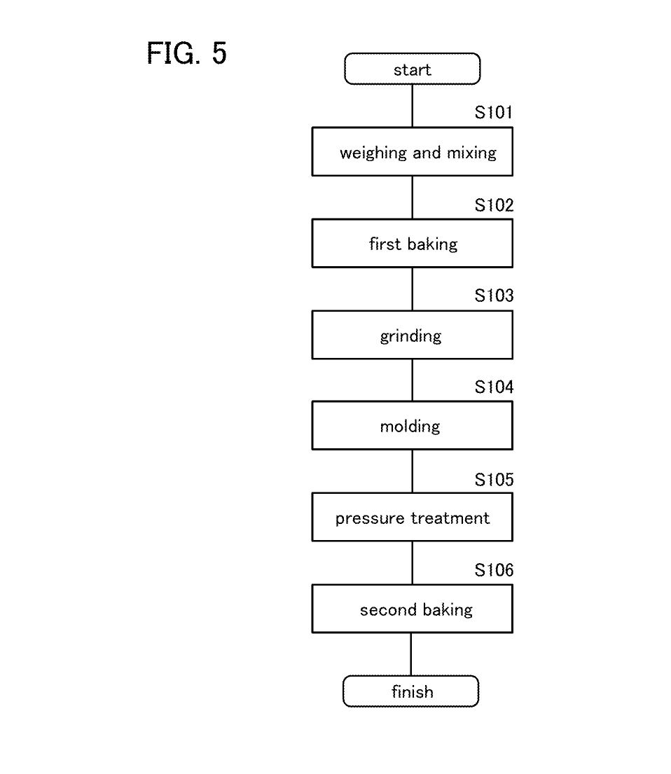

FIG. 5 illustrates an example of a fabrication process of a sputtering target.

First, raw materials are weighed and are mixed in a predetermined molar ratio (step S101).

In this embodiment, description is given on the case where an oxide powder containing In, M, and Zn (also referred to as an In-M-Zn oxide powder) is obtained as the oxide powder containing a plurality of metal elements.

Specifically, an InO_{X} oxide powder, a MO_{Y} oxide powder, and a ZnO_{Z} oxide powder are prepared and mixed in a predetermined molar ratio. Note that X, Y, and Z are each a given positive number; for example, X, Y, and Z are 1.5, 1.5, and 1, respectively.

It is needless to say that the above oxide powders are examples, and oxide powders can be selected as appropriate in order to obtain a desired composition. Note that M refers to Ga, Sn, Hf, Al, La, Ce, Pr, Nd, Sm, Eu, Gd, Tb, Dy, Ho, Er, Tm, Yb, or Lu. Although the case where three kinds of oxide powders are used is shown as an example in this embodiment, one embodiment of the present invention is not limited thereto. For example, this embodiment may be applied to the case where four or more kinds of oxide powders are used or the case where one or two kinds of oxide powders are used.

The predetermined molar ratio of the InO_{X} oxide powder to MO_{Y} oxide powder and the ZnO_{Z} powder is, for example, 2:2:1, 8:4:3, 3:1:1, 1:1:1, 4:2:3, 1:1:2, 3:1:4, or 3:1:2. With such a molar ratio, a sputtering target including a polycrystalline oxide with high crystallinity can be obtained easily later.

Next, an In-M-Zn oxide is obtained by performing first baking on the InO_{X} oxide powder, the MO_{Y} oxide powder, and the ZnO_{Z} oxide powder which are mixed in a predetermined molar ratio (Step S102).

Note that the first baking is performed in an inert atmosphere, an oxidation atmosphere, or a reduced-pressure atmosphere at a temperature higher than or equal to 400° C. and lower than or equal to 1700° C., preferably higher than or equal to 900° C. and lower than or equal to 1500° C. The first baking is performed for longer than or equal to 3 minutes and shorter than or equal to 24 hours, preferably longer than or equal to 30 minutes and shorter than or equal to 17 hours, more preferably longer than or equal to 30 minutes and shorter than or equal to 5 hours, for example. When the first baking is performed under the above conditions, secondary reactions other than the main reaction can be suppressed, and the concentration of impurities in the In-M-Zn oxide powder can be reduced. Accordingly, the crystallinity of the In-M-Zn oxide powder can be increased.

The first baking may be performed plural times at different temperatures and/or in different atmospheres. For example, the In-M-Zn oxide powder may be first held at a first temperature in a first atmosphere and then at a second temperature in a second atmosphere. Specifically, it is preferable that the first atmosphere be an inert atmosphere or a reduced-pressure atmosphere and the second atmosphere be an oxidation atmosphere. This is because oxygen vacancies are generated in the In-M-Zn oxide when impurities contained in the In-M-Zn oxide powder are reduced in the first atmosphere. Therefore, it is preferable that oxygen vacancies in the obtained In-M-Zn oxide be reduced in the second atmosphere. The impurity concentration and oxygen vacancies in the In-M-Zn oxide powder are reduced, whereby the crystallinity of the In-M-Zn oxide powder can be increased.

Next, the In-M-Zn oxide powder is obtained by grinding the In-M-Zn oxide that is a reaction product (Step S103).

The In-M-Zn oxide has a high proportion of planes parallel to the a-b plane. Therefore, the obtained In-M-Zn oxide powder includes many flat plate-like crystal grains whose top and bottom surfaces are parallel to the a-b plane. Moreover, the crystal of the In-M-Zn oxide is in many cases a hexagonal crystal; therefore, in many cases, the above flat plate-like crystal grains each have the shape of a hexagonal prism whose top and bottom surfaces are approximately equilateral hexagons each having interior angles of 120°.

Note that it is preferable that the grinding be performed so that the average grain size of the In-M-Zn oxide powder is less than or equal to 3 μm, preferably less than or equal to 2.5 μm, more preferably less than or equal to 2 μm. After the grinding, the In-M-Zn oxide powder whose grain size is less than or equal to 3 μm, preferably less than or equal to 2.5 μm, more preferably less than or equal to 2 μm may be sorted using a grain size filter.

Next, the In-M-Zn oxide powder is spread over a mold and molded; accordingly, a molded body is formed (Step S104). Here, molding refers to spreading powder or the like over a mold to obtain a uniform thickness. Specifically, the In-M-Zn oxide powder is introduced to the mold, and then vibration is externally applied so that the In-M-Zn oxide powder is molded. Alternatively, the In-M-Zn oxide powder is introduced to the mold, and then molding is performed using a roller or the like so as to obtain a uniform thickness.

Note that in the step S104, slurry in which the In-M-Zn oxide powder is mixed with water, a dispersant, and a binder may be molded. In that case, the slurry is poured into the mold and then molded by sucking the mold from the bottom. After that, drying treatment is performed on a molded body after the mold is sucked. The drying treatment is preferably natural drying because the molded body is less likely to be cracked. After that, the molded body is subjected to heat treatment at a temperature higher than or equal to 300° C. and lower than or equal to 700° C., so that residual moisture or the like which cannot be taken out by natural drying is removed.

When the In-M-Zn oxide powder including many flat plate-like crystal grains whose top and bottom surfaces are parallel to the a-b plane is spread over the mold and molded, the crystal grains are arranged with the planes which are parallel to the a-b plane thereof facing upward. Therefore, the proportion of the planes which are parallel to the a-b plane can be increased in the obtained molded body. Note that the mold may be formed of a metal or an oxide and the upper shape thereof is rectangular or rounded.

The obtained molded body is subjected to pressure treatment (Step S105). The pressure treatment may be performed in any manner as long as the molded body can be pressed. For example, a weight which is formed of the same kind of material as the mold can be used. Alternatively, the In-M-Zn oxide powder may be pressed under a high pressure using compressed air. Besides, the pressure treatment can be performed using a known technique. The pressure treatment performed on the molded body enables a crystal part in the In-M-Zn oxide included in the molded body to have high orientation. Further, a void in the molded body can be made smaller.

Next, second baking is performed on the molded body which has been subjected to the pressure treatment, so that a sintered body is formed (Step S106). The second baking is performed under conditions and methods similar to those of the first baking. The crystallinity of a sintered body can be increased by performing the second baking. Note that the pressure treatment may be performed at the same time as the second baking.

Next, finishing treatment is performed on the sintered body, so that a sputtering target is obtained. Specifically, the sintered body is divided or grounded so as to adjust the length, the width, and the thickness. Further, abnormal discharge might occur when a surface of the sintered body has minute unevenness; therefore, polishing treatment is performed on the surface. The polishing treatment is preferably performed by chemical mechanical polishing (CMP).

Through the above steps, a sputtering target including a polycrystalline oxide containing a plurality of crystal grains can be formed. An oxide semiconductor film with high crystallinity can be formed with the sputtering target obtained through the process of this embodiment.

Note that the sputtering target formed in such a manner can have high density. When the density of the sputtering target is increased, the density of a film which is formed can also be increased. Specifically, the relative density of the sputtering target can be higher than or equal to 90%, preferably higher than or equal to 95%, more preferably higher than or equal to 99%.

The methods and structures described in this embodiment can be combined as appropriate with any of the methods and structures described in the other embodiments.

### Embodiment 3

In this embodiment, a structure example of a transistor to which the oxide semiconductor film described in Embodiment 1 is applied will be described with reference to drawings.

### <Structure Example of Transistor>

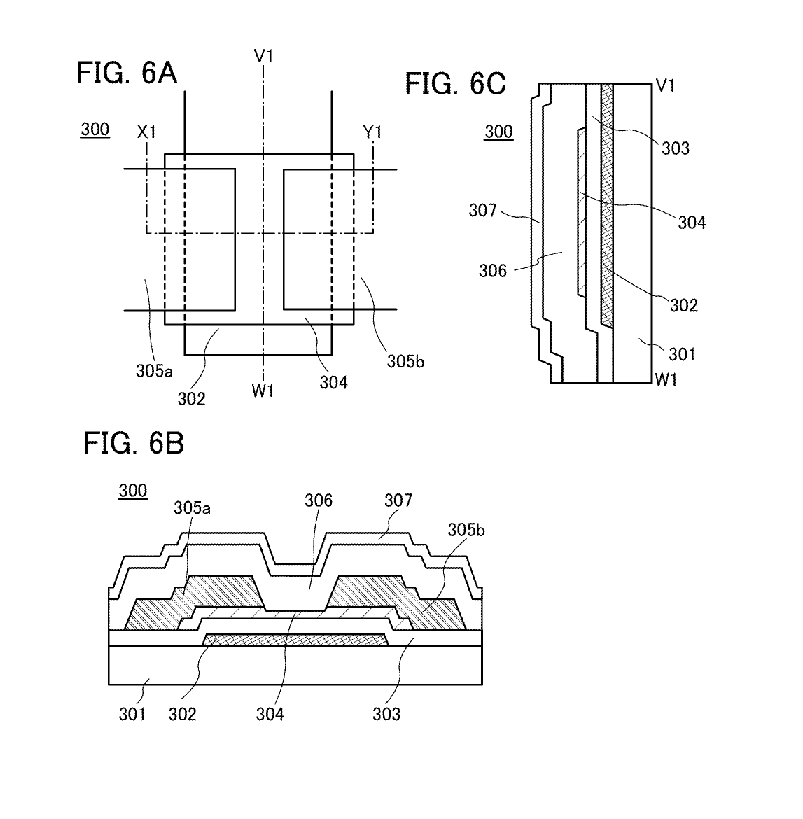

FIGS. 6A to 6C illustrate a structure example of a transistor 300. The transistor 300 exemplified by this structure example is a bottom-gate transistor. FIG. 6A is a plan view of the transistor 300, FIG. 6B is a cross-sectional view taken along line X1-Y1 in FIG. 6A, and FIG. 6C is a cross-sectional view taken along line V1-W1 in FIG. 6A.

The transistor 300 includes a gate electrode layer 302 over a substrate 301, an insulating layer 303 over the substrate 301 and the gate electrode layer 302, an oxide semiconductor film 304 over the insulating layer 303, which overlaps with the gate electrode layer 302, and a source electrode layer 305a and a drain electrode layer 305b which are in contact with the top surface of the oxide semiconductor film 304. Moreover, an insulating layer 306 covers the insulating layer 303, the oxide semiconductor film 304, the source electrode layer 305a, and the drain electrode layer 305b; and an insulating layer 307 is over the insulating layer 306.

The oxide semiconductor film of one embodiment of the present invention can be applied to the oxide semiconductor film 304 included in the transistor 300.

Components of the transistor 300 are described in detail below.

There is no particular limitation on the property of a material and the like of the substrate 301 as long as the material has heat resistance enough to withstand at least heat treatment which will be performed later. For example, a glass substrate, a ceramic substrate, a quartz substrate, a sapphire substrate, or a yttria-stabilized zirconia (YSZ) substrate may be used as the substrate 301. Alternatively, a single crystal semiconductor substrate or a polycrystalline semiconductor substrate made of silicon, silicon carbide, or the like, a compound semiconductor substrate made of silicon germanium or the like, an SOI substrate, or the like can be used as the substrate 301. Still alternatively, any of these substrates provided with a semiconductor element may be used as the substrate 301.

Still alternatively, a flexible substrate such as a plastic substrate may be used as the substrate 301, and the transistor 300 may be provided directly on the flexible substrate. Further alternatively, a separation layer may be provided between the substrate 301 and the transistor 300. The separation layer can be used when part or the whole of the transistor formed over the separation layer is formed and separated from the substrate 301 and transferred to another substrate. Thus, the transistor 300 can be transferred to a substrate having low heat resistance or a flexible substrate.

The gate electrode layer 302 can be formed using a metal selected from aluminum, chromium, copper, tantalum, titanium, molybdenum, and tungsten; an alloy containing any of these metals as a component; an alloy containing any of these metals in combination; or the like. Further, one or more metals selected from manganese and zirconium may be used. Furthermore, the gate electrode layer 302 may have a single-layer structure or a stacked-layer structure of two or more layers. For example, a single-layer structure of an aluminum film containing silicon, a two-layer structure in which a titanium film is stacked over an aluminum film, a two-layer structure in which a titanium film is stacked over a titanium nitride film, a two-layer structure in which a tungsten film is stacked over a titanium nitride film, a two-layer structure in which a tungsten film is stacked over a tantalum nitride film or a tungsten nitride film, a three-layer structure in which a titanium film, an aluminum film, and a titanium film are stacked in this order, and the like can be given. Alternatively, an alloy film containing aluminum and one or more metals selected from titanium, tantalum, tungsten, molybdenum, chromium, neodymium, and scandium; or a nitride film of the alloy film may be used.

The gate electrode layer 302 can also be formed using a light-transmitting conductive material such as indium tin oxide, indium oxide containing tungsten oxide, indium zinc oxide containing tungsten oxide, indium oxide containing titanium oxide, indium tin oxide containing titanium oxide, indium zinc oxide, or indium tin oxide to which silicon oxide is added. It is also possible to have a stacked-layer structure formed using the above light-transmitting conductive material and the above metal.

Further, an In—Ga—Zn-based oxynitride semiconductor film, an In—Sn-based oxynitride semiconductor film, an In—Ga-based oxynitride semiconductor film, an In—Zn-based oxynitride semiconductor film, a Sn-based oxynitride semiconductor film, an In-based oxynitride semiconductor film, a film of metal nitride (such as InN or ZnN), or the like may be provided between the gate electrode layer 302 and the insulating layer 303. These films each have a work function higher than or equal to 5 eV, preferably higher than or equal to 5.5 eV, which is higher than the electron affinity of the oxide semiconductor. Thus, the threshold voltage of the transistor including an oxide semiconductor can be shifted in the positive direction, and what is called a normally-off switching element can be achieved. For example, in the case of using an In—Ga—Zn-based oxynitride semiconductor film, an In—Ga—Zn-based oxynitride semiconductor film having a higher nitrogen concentration than at least the oxide semiconductor film 304, specifically, an In—Ga—Zn-based oxynitride semiconductor film having a nitrogen concentration of 7 at. % or higher is used.

The insulating layer 303 functions as a gate insulating film. The insulating layer 303 in contact with the bottom surface of the oxide semiconductor film 304 is preferably an amorphous film.

The insulating layer 303 may be formed to have a single-layer structure or a stacked-layer structure using, for example, one or more of silicon oxide, silicon oxynitride, silicon nitride oxide, silicon nitride, aluminum oxide, hafnium oxide, gallium oxide, Ga—Zn-based metal oxide, silicon nitride, and the like.

The insulating layer 303 may be formed using a high-k material such as hafnium silicate (HfSiOₓ), hafnium silicate to which nitrogen is added (HfSiₓO_{y}N_{z}), hafnium aluminate to which nitrogen is added (HfAlₓO_{y}N_{z}), hafnium oxide, or yttrium oxide, so that gate leakage current of the transistor can be reduced.

The source electrode layer 305a and the drain electrode layer 305b can be formed to have a single-layer structure or a stacked-layer structure using, as a conductive material, any of metals such as aluminum, titanium, chromium, nickel, copper, yttrium, zirconium, molybdenum, silver, tantalum, and tungsten, or an alloy containing any of these metals as its main component. For example, a single-layer structure of an aluminum film containing silicon, a two-layer structure in which a titanium film is stacked over an aluminum film, a two-layer structure in which a titanium film is stacked over a tungsten film, a two-layer structure in which a copper film is stacked over a copper-magnesium-aluminum alloy film, a three-layer structure in which a titanium film or a titanium nitride film, an aluminum film or a copper film, and a titanium film or a titanium nitride film are stacked in this order, a three-layer structure in which a molybdenum film or a molybdenum nitride film, an aluminum film or a copper film, and a molybdenum film or a molybdenum nitride film are stacked in this order, and the like can be given. Note that a transparent conductive material containing indium oxide, tin oxide, or zinc oxide may be used.

The insulating layer 306 is preferably formed using an oxide insulating film containing oxygen at a higher proportion than oxygen in the stoichiometric composition. Part of oxygen is released by heating from the oxide insulating film containing oxygen at a higher proportion than oxygen in the stoichiometric composition. The oxide insulating film containing oxygen at a higher proportion than oxygen in the stoichiometric composition is an oxide insulating film in which the amount of released oxygen converted into oxygen atoms is greater than or equal to 1.0×10¹⁸ atoms/cm³, preferably greater than or equal to 3.0×10²⁰ atoms/cm³ in thermal desorption spectroscopy (TDS) analysis.

As the insulating layer 306, a silicon oxide film, a silicon oxynitride film, or the like can be formed.

Note that the insulating layer 306 also functions as a film which relieves damage to the oxide semiconductor film 304 at the time of forming the insulating layer 307 later.

Alternatively, an oxide film transmitting oxygen may be provided between the insulating layer 306 and the oxide semiconductor film 304.

As the oxide film transmitting oxygen, a silicon oxide film, a silicon oxynitride film, or the like can be formed. Note that in this specification, a “silicon oxynitride film” refers to a film that contains oxygen at a higher proportion than nitrogen, and a “silicon nitride oxide film” refers to a film that contains nitrogen at a higher proportion than oxygen.

The insulating layer 307 can be formed using an insulating film having a blocking effect against oxygen, hydrogen, water, and the like. It is possible to prevent outward diffusion of oxygen from the oxide semiconductor film 304 and entry of hydrogen, water, or the like into the oxide semiconductor film 304 from the outside by providing the insulating layer 307 over the insulating layer 306. As for the insulating film having a blocking effect against oxygen, hydrogen, water, and the like, a silicon nitride film, a silicon nitride oxide film, an aluminum oxide film, an aluminum oxynitride film, a gallium oxide film, a gallium oxynitride film, an yttrium oxide film, an yttrium oxynitride film, a hafnium oxide film, and a hafnium oxynitride film can be given as examples.

Next, an example of a fabrication method of the transistor 300 exemplified in FIGS. 6A to 6C is described.

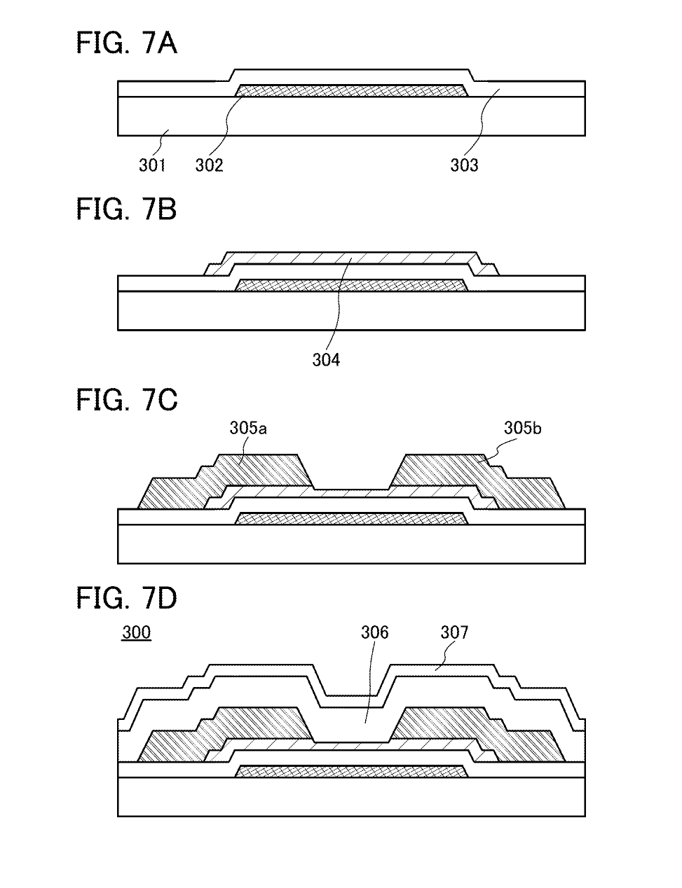

First, as illustrated in FIG. 7A, the gate electrode layer 302 is formed over the substrate 301, and the insulating layer 303 is formed over the gate electrode layer 302.

A formation method of the gate electrode layer 302 is described below. First, a conductive film is formed by a sputtering method, a CVD method, an evaporation method, or the like and then a resist mask is formed over the conductive film using a first photomask by a photolithography process. Then, part of the conductive film is etched using the resist mask to form the gate electrode layer 302. After that, the resist mask is removed.

Note that instead of the above formation method, the gate electrode layer 302 may be formed by an electrolytic plating method, a printing method, an ink-jet method, or the like.

The insulating layer 303 serving as a gate insulating layer is formed by a sputtering method, a CVD method, an evaporation method, or the like.

In the case where the insulating layer 303 is formed using a silicon oxide film, a silicon oxynitride film, or a silicon nitride oxide film, a deposition gas containing silicon and an oxidizing gas are preferably used as a source gas. Typical examples of the deposition gas containing silicon include silane, disilane, trisilane, and silane fluoride. As the oxidizing gas, oxygen, ozone, dinitrogen monoxide, and nitrogen dioxide can be given as examples.

In the case of forming a silicon nitride film as the insulating layer 303, it is preferable to use a two-step formation method. First, a first silicon nitride film with a small number of defects is formed by a plasma CVD method in which a mixed gas of silane, nitrogen, and ammonia is used as a source gas. Then, a second silicon nitride film in which the hydrogen concentration is low and hydrogen can be blocked is formed by switching the source gas to a mixed gas of silane and nitrogen. With such a formation method, a silicon nitride film with a small number of defects and a blocking effect against hydrogen can be formed as the insulating layer 303.

Moreover, in the case of forming a gallium oxide film as the insulating layer 303, a metal organic chemical vapor deposition (MOCVD) method can be employed.

Next, as illustrated in FIG. 7B, the oxide semiconductor film 304 is formed over the insulating layer 303.

A formation method of the oxide semiconductor film 304 is described below. First, an oxide semiconductor film is formed using the method described in Embodiment 1. Then, a resist mask is formed over the oxide semiconductor film using a second photomask by a photolithography process. Then, part of the oxide semiconductor film is etched using the resist mask to form the oxide semiconductor film 304. After that, the resist mask is removed.

After that, heat treatment may be performed. In such a case, the heat treatment is preferably performed under an atmosphere containing oxygen.

Next, as illustrated in FIG. 7C, the source electrode layer 305a and the drain electrode layer 305b are formed.

A formation method of the source electrode layer 305a and the drain electrode layer 305b is described below. First, a conductive film is formed by a sputtering method, a CVD method, an evaporation method, or the like. Then, a resist mask is formed over the conductive film using a third photomask by a photolithography process. Then, part of the conductive film is etched using the resist mask to form the source electrode layer 305a and the drain electrode layer 305b. After that, the resist mask is removed.

Note that as illustrated in FIG. 7C, the upper part of the oxide semiconductor film 304 is in some cases partly etched and thinned by the etching of the conductive film.

Next, as illustrated in FIG. 7D, the insulating layer 306 is formed over the oxide semiconductor film 304, the source electrode layer 305a, and the drain electrode layer 305b, and the insulating layer 307 is successively formed over the insulating layer 306.

In the case where the insulating layer 306 is formed using a silicon oxide film or a silicon oxynitride film, a deposition gas containing silicon and an oxidizing gas are preferably used as a source gas. Typical examples of the deposition gas containing silicon include silane, disilane, trisilane, and silane fluoride. As the oxidizing gas, oxygen, ozone, dinitrogen monoxide, and nitrogen dioxide can be given as examples.

For example, a silicon oxide film or a silicon oxynitride film is formed under the conditions as follows: the substrate placed in a treatment chamber of a plasma CVD apparatus, which is vacuum-evacuated, is held at a temperature higher than or equal to 180° C. and lower than or equal to 260° C., preferably higher than or equal to 200° C. and lower than or equal to 240° C., the pressure is greater than or equal to 100 Pa and less than or equal to 250 Pa, preferably greater than or equal to 100 Pa and less than or equal to 200 Pa with introduction of a source gas into the treatment chamber, and high-frequency power higher than or equal to 0.17 W/cm² and lower than or equal to 0.5 W/cm², preferably higher than or equal to 0.25 W/cm² and lower than or equal to 0.35 W/cm² is supplied to an electrode provided in the treatment chamber.

As the film formation conditions, the high-frequency power having the above power density is supplied to the treatment chamber having the above pressure, whereby the degradation efficiency of the source gas in plasma is increased, oxygen radicals are increased, and oxidation of the source gas is promoted; therefore, oxygen is contained in the oxide insulating film at a higher proportion than oxygen in the stoichiometric composition. However, in the case where the substrate temperature is within the above temperature range, the bond between silicon and oxygen is weak, and accordingly, part of oxygen is released by heating. Thus, it is possible to form an oxide insulating film which contains oxygen at a higher proportion than oxygen in the stoichiometric composition and from which part of oxygen is released by heating.

Further, in the case of providing an oxide insulating film between the oxide semiconductor film 304 and the insulating layer 306, the oxide insulating film serves as a protective film of the oxide semiconductor film 304 in the steps of forming the insulating layer 306. Thus, the insulating layer 306 can be formed using the high-frequency power having a high power density while damage to the oxide semiconductor film 304 is reduced.

For example, a silicon oxide film or a silicon oxynitride film is formed as the oxide insulating film under the conditions as follows: the substrate placed in a treatment chamber of a plasma CVD apparatus, which is vacuum-evacuated, is held at a temperature higher than or equal to 180° C. and lower than or equal to 400° C., preferably higher than or equal to 200° C. and lower than or equal to 370° C., the pressure is greater than or equal to 20 Pa and less than or equal to 250 Pa, preferably greater than or equal to 100 Pa and less than or equal to 250 Pa with introduction of a source gas into the treatment chamber, and high-frequency power is supplied to an electrode provided in the treatment chamber. Further, when the pressure in the treatment chamber is greater than or equal to 100 Pa and less than or equal to 250 Pa, damage to the oxide semiconductor film 304 can be reduced.

A deposition gas containing silicon and an oxidizing gas are preferably used as a source gas of the oxide insulating film. Typical examples of the deposition gas containing silicon include silane, disilane, trisilane, and silane fluoride. As the oxidizing gas, oxygen, ozone, dinitrogen monoxide, and nitrogen dioxide can be given as examples.

The insulating layer 307 can be formed by a sputtering method, a CVD method, or the like.

In the case where the insulating layer 307 is formed using a silicon nitride film or a silicon nitride oxide film, a deposition gas containing silicon, an oxidizing gas, and a gas containing nitrogen are preferably used as a source gas. Typical examples of the deposition gas containing silicon include silane, disilane, trisilane, and silane fluoride. As the oxidizing gas, oxygen, ozone, dinitrogen monoxide, and nitrogen dioxide can be given as examples. As the gas containing nitrogen, nitrogen and ammonia can be given as examples.

Through the above process, the transistor 300 can be formed.

### <Another Structure Example of Transistor>

A structure example of a top-gate transistor to which the oxide semiconductor film of one embodiment of the present invention can be applied is described below.

Note that descriptions of components having structures or functions similar to those of the above, which are denoted by the same reference numerals, are omitted below.

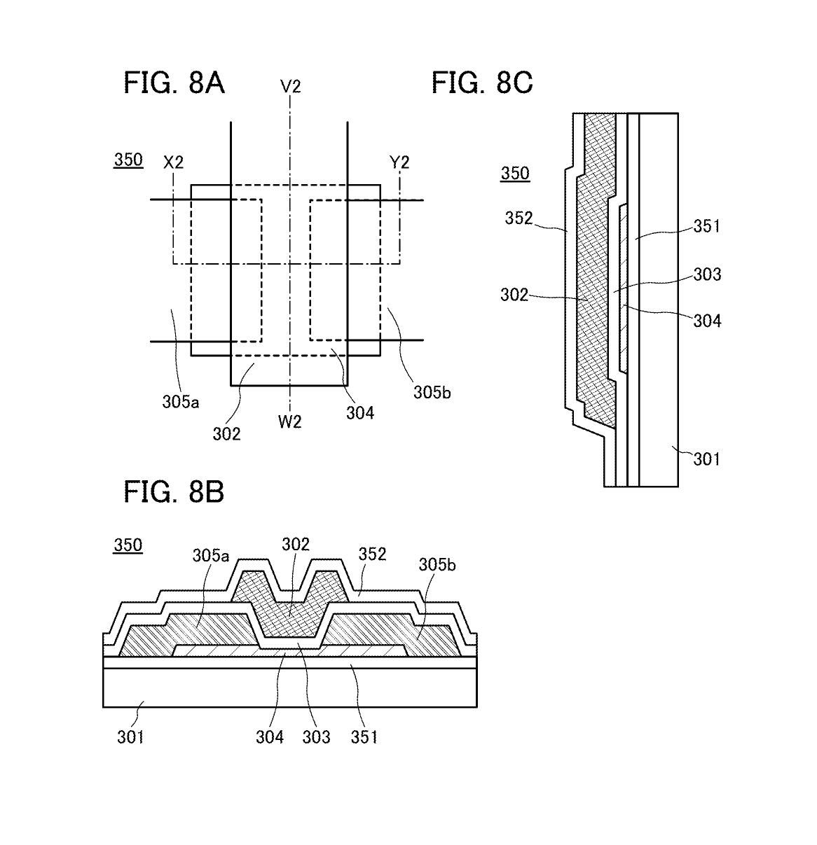

FIGS. 8A to 8C illustrate a structure example of a transistor 350. FIG. 8A is a plan view of the transistor 350, FIG. 8B is a cross-sectional view taken along line X2-Y2 in FIG. 8A, and FIG. 8C is a cross-sectional view taken along line V2-W2 in FIG. 8A.

The transistor 350 includes the oxide semiconductor film 304 over the substrate 301 provided with an insulating layer 351, the source electrode layer 305a and the drain electrode layer 305b which are in contact with the top surface of the oxide semiconductor film 304, the insulating layer 303 over the oxide semiconductor film 304, the source electrode layer 305a, and the drain electrode layer 305b, and the gate electrode layer 302 over the insulating layer 303, which overlaps with the oxide semiconductor film 304. Moreover, an insulating layer 352 covers the insulating layer 303 and the gate electrode layer 302.

The oxide semiconductor film of one embodiment of the present invention can be applied to the oxide semiconductor film 304 included in the transistor 350.

The insulating layer 351 has a function of suppressing diffusion of impurities from the substrate 301 to the oxide semiconductor film 304. For example, a structure similar to that of the insulating layer 307 can be employed. Note that the insulating layer 351 is not necessarily provided when not needed.

The insulating layer 352 can be formed using an insulating film having a blocking effect against oxygen, hydrogen, water, and the like in a manner similar to that of the insulating layer 307. Note that the insulating layer 352 is not necessarily provided when not needed.

The methods and structures described in this embodiment can be combined as appropriate with any of the methods and structures described in the other embodiments.

### Embodiment 4

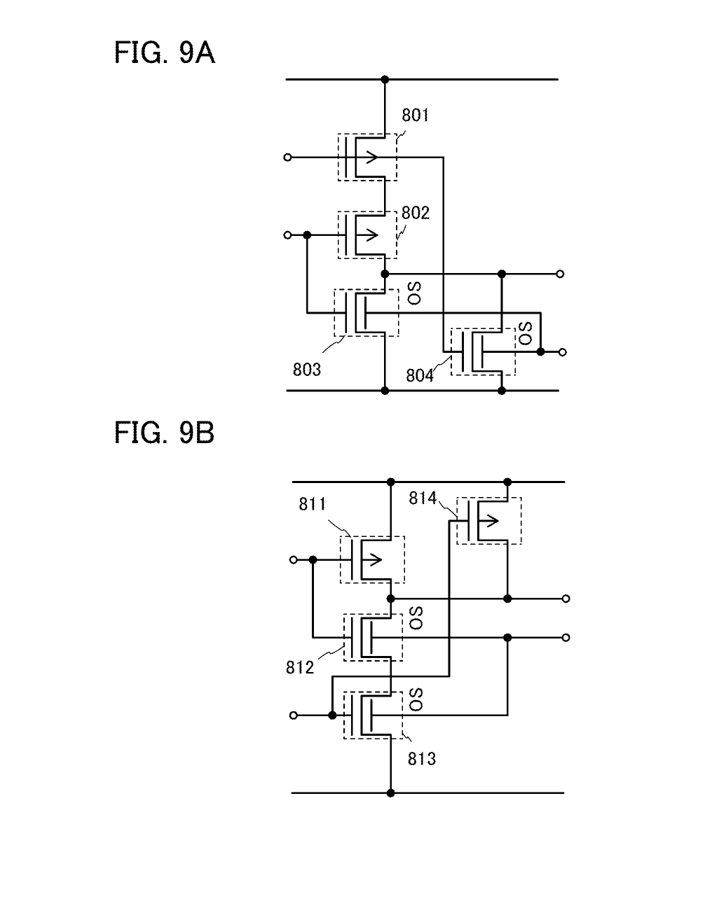

FIG. 9A illustrates an example of a circuit diagram of a NOR circuit, which is a logic circuit, as an example of the semiconductor device of one embodiment of the present invention. FIG. 9B is a circuit diagram of a NAND circuit.

In the NOR circuit in FIG. 9A, p-channel transistors 801 and 802 are transistors in each of which a channel formation region is formed using a semiconductor material (e.g., silicon) other than an oxide semiconductor, and n-channel transistors 803 and 804 each include an oxide stack including an oxide semiconductor and each have a structure similar to that of the transistor described in Embodiment 3.

A transistor including a semiconductor material such as silicon can easily operate at high speed. In contrast, a transistor including an oxide semiconductor enables charge to be held for a long time owing to its characteristics.

To miniaturize the logic circuit, it is preferable that the n-channel transistors 803 and 804 be stacked over the p-channel transistors 801 and 802. For example, the transistors 801 and 802 can be formed using a single crystal silicon substrate, and the transistors 803 and 804 can be formed over the transistors 801 and 802 with an insulating layer provided therebetween.

In the NAND circuit in FIG. 9B, p-channel transistors 811 and 814 are transistors in each of which a channel formation region is formed using a semiconductor material (e.g., silicon) other than an oxide semiconductor, and n-channel transistors 812 and 813 each include an oxide semiconductor film and each have a structure similar to that of the transistor described in Embodiment 3.

Note that in the NAND circuit in FIG. 9B, the transistors 812 and 813 each have a structure in which the oxide semiconductor film is provided between a pair of gate electrodes (a first gate electrode and a second gate electrode), and by controlling the potential of the second gate electrode, the threshold voltages of the transistors 812 and 813 are further shifted in the positive direction and, preferably, the transistors can be normally off.

As in the NOR circuit in FIG. 9A, to miniaturize the logic circuit, it is preferable that the n-channel transistors 812 and 813 be stacked over the p-channel transistors 811 and 814.

By using a transistor including an oxide semiconductor for a channel formation region and having extremely small off-state current for the semiconductor device described in this embodiment, power consumption of the semiconductor device can be significantly reduced.

A semiconductor device which is miniaturized, is highly integrated, and has stable and excellent electrical characteristics by stacking semiconductor elements including different semiconductor materials and a fabrication method of the semiconductor device can be provided.

In addition, by employing the structure of the transistor including the oxide semiconductor film of one embodiment of the present invention, a NOR circuit and a NAND circuit with high reliability and stable characteristics can be provided.

Note that the NOR circuit and the NAND circuit including the transistor described in Embodiment 3 are described as examples in this embodiment; however, the present invention is not particularly limited to the circuits, and an AND circuit, an OR circuit, or the like can be formed using the transistor described in Embodiment 3.

Alternatively, it is possible to fabricate a display device by combining a display element with any of the transistors described in this embodiment and the other embodiments. For example, a display element, a display device which is a device including a display element, a light-emitting element, and a light-emitting device which is a device including a light-emitting element can employ various modes and can include various elements. For example, a display medium, whose contrast, luminance, reflectivity, transmittance, or the like changes by electromagnetic action, such as an EL (electroluminescence) element (e.g., an EL element including organic and inorganic materials, an organic EL element, or an inorganic EL element), an LED (e.g., a white LED, a red LED, a green LED, or a blue LED), a transistor (a transistor which emits light depending on the amount of current), an electron emitter, a liquid crystal element, electronic ink, an electrophoretic element, a grating light valve (GLV), a plasma display panel (PDP), a digital micromirror device (DMD), a piezoelectric ceramic display, or a carbon nanotube, can be used as a display element, a display device, a light-emitting element, or a light-emitting device. Note that examples of display devices having EL elements include an EL display. Display devices having electron emitters include a field emission display (FED), an SED-type flat panel display (SED: surface-conduction electron-emitter display), and the like. Examples of display devices including liquid crystal elements include a liquid crystal display (e.g., a transmissive liquid crystal display, a transflective liquid crystal display, a reflective liquid crystal display, a direct-view liquid crystal display, or a projection liquid crystal display). Examples of display devices having electronic ink or electrophoretic elements include electronic paper.

The methods and structures described in this embodiment can be combined as appropriate with any of the methods and structures described in the other embodiments.

### Embodiment 5

In this embodiment, an example of a semiconductor device (memory device) which includes the transistor described in Embodiment 3, which can hold stored data even when not powered, and which has an unlimited number of write cycles will be described with reference to drawings.

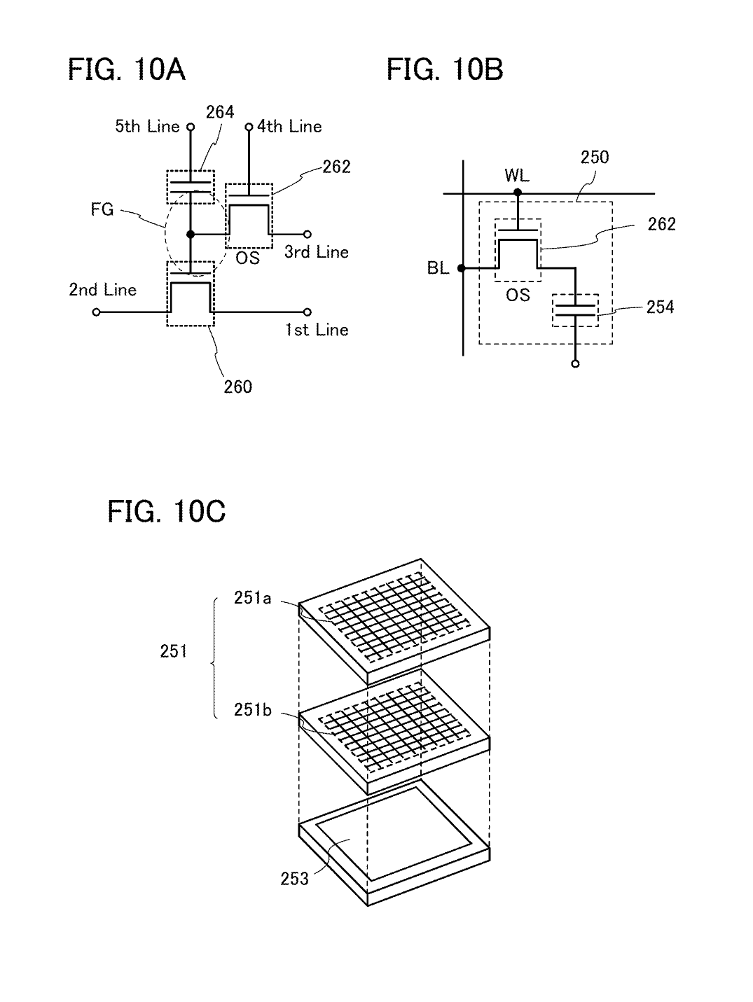

FIG. 10A is a circuit diagram illustrating the semiconductor device of this embodiment.

A transistor including a semiconductor material (e.g., silicon) other than an oxide semiconductor can be applied to a transistor 260 illustrated in FIG. 10A and thus the transistor 260 can easily operate at high speed. Further, a structure similar to that of the transistor described in Embodiment 3, which includes an oxide semiconductor film of one embodiment of the present invention, can be applied to a transistor 262 to enable charge to be held for a long time owing to its characteristics.

Although all the transistors are n-channel transistors here, p-channel transistors can be used as the transistors used for the semiconductor device described in this embodiment.

In FIG. 10A, a first wiring (1st Line) is electrically connected to a source electrode layer of the transistor 260, and a second wiring (2nd Line) is electrically connected to a drain electrode layer of the transistor 260. A third wiring (3rd Line) is electrically connected to one of a source electrode layer and a drain electrode layer of the transistor 262, and a fourth wiring (4th Line) is electrically connected to a gate electrode layer of the transistor 262. A gate electrode layer of the transistor 260 and the other of the source electrode layer and the drain electrode layer of the transistor 262 are electrically connected to one electrode of a capacitor 264. A fifth wiring (5th Line) and the other electrode of the capacitor 264 are electrically connected to each other.

The semiconductor device in FIG. 10A utilizes a characteristic in which the potential of the gate electrode layer of the transistor 260 can be held, and thus enables data writing, holding, and reading as follows.

Writing and holding of data is described. First, the potential of the fourth wiring is set to a potential at which the transistor 262 is turned on, so that the transistor 262 is turned on. Thus, the potential of the third wiring is applied to the gate electrode layer of the transistor 260 and the capacitor 264. In other words, a predetermined charge is supplied to the gate electrode layer of the transistor 260 (i.e., writing of data). Here, charge for supplying either of two different potential levels (hereinafter referred to as low-level charge and high-level charge) is given. After that, the potential of the fourth wiring is set to a potential at which the transistor 262 is turned off, so that the transistor 262 is turned off. Thus, the charge given to the gate electrode layer of the transistor 260 is held (i.e., holding of data).

The off-state current of the transistor 262 is extremely low; therefore, the charge of the gate electrode layer of the transistor 260 is held for a long time.

Next, reading of data is described. By supplying an appropriate potential (reading potential) to the fifth wiring while supplying a predetermined potential (constant potential) to the first wiring, the potential of the second wiring varies depending on the amount of charge held in the gate electrode layer of the transistor 260. This is because in general, when the transistor 260 is an n-channel transistor, an apparent threshold voltage Vₜₕ_{_{—}}_{H} in the case where a High level charge is given to the gate electrode layer of the transistor 260 is lower than an apparent threshold voltage Vₜₕ_{_{—}}_{L} in the case where a Low level charge is given to the gate electrode layer of the transistor 260. Here, an apparent threshold voltage refers to the potential of the fifth wiring, which is needed to turn on the transistor 260. Thus, the potential of the fifth wiring is set to a potential V₀ which is between Vₜₕ_{_{—}}_{H} and Vₜₕ_{_{—}}_{L}, whereby charge supplied to the gate electrode layer of the transistor 260 can be determined. For example, in the case where High level charge is given in writing, when the potential of the fifth wiring is set to V₀ (>Vₜₕ_{_{—}}_{H}), the transistor 260 is turned on. In the case where Low level charge is given in writing, even when the potential of the fifth wiring is set to V₀ (<Vₜₕ_{_{—}}_{L}), the transistor 260 remains in an off state. Therefore, the stored data can be read by the potential of the second wiring.

Note that in the case where memory cells are arrayed to be used, only data of desired memory cells needs to be read. In the case where such reading is not performed, a potential at which the transistor 260 is turned off regardless of the state of the gate electrode layer, that is, a potential lower than Vₜₕ_{_{—}}_{H} may be supplied to the fifth wiring. Alternatively, a potential at which the transistor 260 is turned on regardless of the state of the gate electrode layer, that is, a potential higher than Vₜₕ_{_{—}}_{L} may be given to the fifth wiring.

FIG. 10B illustrates another example of one embodiment of the structure of the storage device. FIG. 10B illustrates an example of a circuit configuration of a semiconductor device, and FIG. 10C is a conceptual diagram illustrating an example of a semiconductor device. First, the semiconductor device illustrated in FIG. 10B is described, and then, the semiconductor device illustrated in FIG. 10C is described below.

In the semiconductor device illustrated in FIG. 10B, a bit line BL is electrically connected to the source electrode layer or the drain electrode layer of the transistor 262, a word line WL is electrically connected to the gate electrode layer of the transistor 262, and the source electrode layer or the drain electrode layer of the transistor 262 is electrically connected to one electrode of a capacitor 254.

Here, the transistor 262 including an oxide semiconductor has extremely low off-state current. For that reason, a potential of the one electrode of the capacitor 254 (or a charge accumulated in the capacitor 254) can be held for an extremely long time by turning off the transistor 262.

Next, writing and holding of data in the semiconductor device (a memory cell 250) illustrated in FIG. 10B are described.

First, the potential of the word line WL is set to a potential at which the transistor 262 is turned on, so that the transistor 262 is turned on. Accordingly, the potential of the bit line BL is supplied to the one electrode of the capacitor 254 (i.e., writing of data). After that, the potential of the word line WL is set to a potential at which the transistor 262 is turned off, so that the transistor 262 is turned off. Thus, the potential of the one electrode of the capacitor 254 is held (i.e., holding of data).

Since the off-state current of the transistor 262 is extremely small, the potential of the one electrode of the capacitor 254 (or the charge accumulated in the capacitor 254) can be held for a long time.

Next, reading of data is described. When the transistor 262 is turned on, the bit line BL which is in a floating state and the capacitor 254 are electrically connected to each other, and the charge is redistributed between the bit line BL and the capacitor 254. As a result, the potential of the bit line BL is changed. The amount of change in potential of the bit line BL varies depending on the potential of the one electrode of the capacitor 254 (or the charge accumulated in the capacitor 254).

For example, the potential of the bit line BL after charge redistribution is (C_{B}×V_{B0}+C×V)/(C_{B}+C), where V is the potential of the one electrode of the capacitor 254, C is the capacitance of the capacitor 254, C_{B} is the capacitance of the bit line BL (hereinafter also referred to as bit line capacitance), and V_{B0} is the potential of the bit line BL before the charge redistribution. Therefore, it can be found that assuming that the memory cell 250 is in either of two states in which the potentials of the one electrode of the capacitor 254 are V₁ and V₀ (V₁>V₀), the potential of the bit line BL in the case of holding the potential V₁ (=(C_{B}×V_{B0}+C×V₁)/(C_{B}+C)) is higher than the potential of the bit line BL in the case of holding the potential V₀ (=(C_{B}×V_{B0}+C×V₀)/(C_{B}+C)).

Then, by comparing the potential of the bit line BL with a predetermined potential, data can be read.

As described above, the semiconductor device illustrated in FIG. 10B can hold charge that is accumulated in the capacitor 254 for a long time because the amount of the off-state current of the transistor 262 is extremely small. In other words, power consumption can be adequately reduced because refresh operation becomes unnecessary or the frequency of refresh operation can be significantly reduced. Moreover, stored data can be held for a long time even when power is not supplied.

Next, the semiconductor device illustrated in FIG. 10C is described.

The semiconductor device illustrated in FIG. 10C includes memory cell arrays 251a and 251b including a plurality of memory cells 250 illustrated in FIG. 10B as memory circuits in an upper portion, and a peripheral circuit 253 in a lower portion which is necessary for operating a memory cell array 251 (the memory cell arrays 251a and 251b). Note that the peripheral circuit 253 is electrically connected to the memory cell array 251.

In the structure illustrated in FIG. 10C, the peripheral circuit 253 can be provided under the memory cell array 251 (the memory cell arrays 251a and 251b). Thus, the size of the semiconductor device can be reduced.

It is preferable that a semiconductor material of a transistor provided in the peripheral circuit 253 be different from that of the transistor 262. For example, silicon, germanium, silicon germanium, silicon carbide, gallium arsenide, or the like can be used, and a single crystal semiconductor is preferably used. Alternatively, an organic semiconductor material or the like may be used. A transistor including such a semiconductor material can operate at sufficiently high speed. Therefore, the transistor can favorably realize a variety of circuits (e.g., a logic circuit or a driver circuit) which needs to operate at high speed.

Note that FIG. 10C illustrates, as an example, the semiconductor device in which two memory cell arrays 251 (the memory cell arrays 251a and 251b) are stacked; however, the number of memory cell arrays which are stacked is not limited thereto. Three or more memory cell arrays may be stacked.

When a transistor including the oxide semiconductor film of one embodiment of the present invention in a channel formation region is used as the transistor 262, stored data can be held for a long time. In other words, power consumption can be adequately reduced because refresh operation becomes unnecessary or the frequency of refresh operation can be significantly reduced.

The methods and structures described in this embodiment can be combined as appropriate with any of the methods and structures described in the other embodiments.

### Embodiment 6

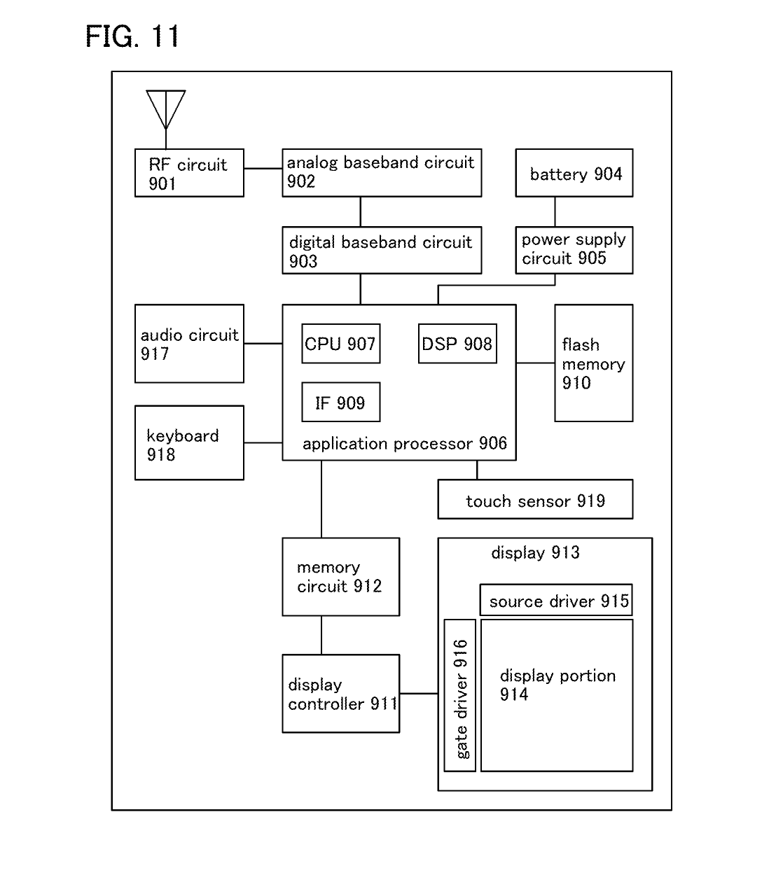

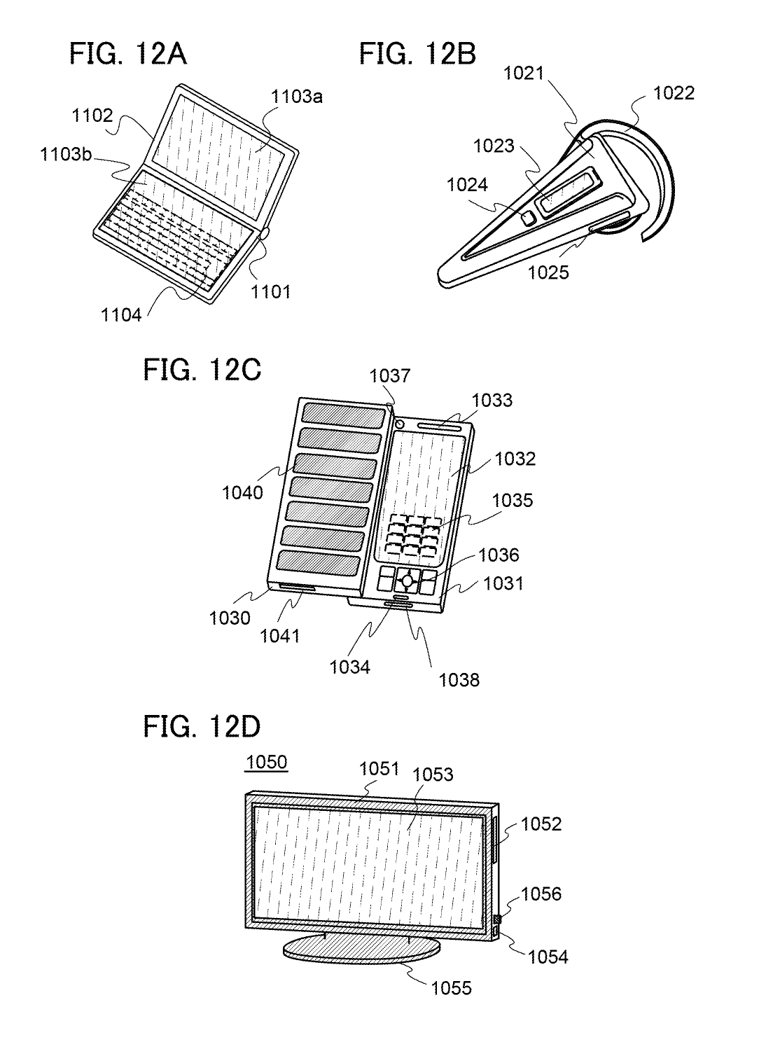

In this embodiment, structures of a semiconductor device including the oxide semiconductor film of one embodiment of the present invention and electronic devices using the semiconductor device will be described with reference to FIG. 11 and FIGS. 12A to 12D.

FIG. 11 is a block diagram of an electronic device including the semiconductor device to which the oxide semiconductor film of one embodiment of the present invention is applied.

FIGS. 12A to 12D are external views of electronic devices each including the semiconductor device to which the oxide semiconductor film of one embodiment of the present invention is applied.

An electronic device illustrated in FIG. 11 includes an RF circuit 901, an analog baseband circuit 902, a digital baseband circuit 903, a battery 904, a power supply circuit 905, an application processor 906, a flash memory 910, a display controller 911, a memory circuit 912, a display 913, a touch sensor 919, an audio circuit 917, a keyboard 918, and the like.

The application processor 906 includes a CPU 907, a DSP 908, and an interface (IF) 909. Moreover, the memory circuit 912 can include an SRAM or a DRAM.

The transistor described in Embodiment 3 is applied to the memory circuit 912, whereby a highly reliable electronic device which can write and read data can be provided.

The transistor described in Embodiment 3 is applied to a register or the like included in the CPU 907 or the DSP 908, whereby a highly reliable electronic device which can write and read data can be provided.

Note that in the case where the off-state leakage current of the transistor described in Embodiment 3 is extremely small, the memory circuit 912 can store data for a long time and can have sufficiently reduced power consumption. Moreover, the CPU 907 or the DSP 908 can store the state before power gating in a register or the like during a period in which the power gating is performed.

Further, the display 913 includes a display portion 914, a source driver 915, and a gate driver 916.

The display portion 914 includes a plurality of pixels arranged in a matrix. The pixel includes a pixel circuit, and the pixel circuit is electrically connected to the gate driver 916.

The transistor described in Embodiment 3 can be used as appropriate in the pixel circuit or the gate driver 916. Accordingly, a highly reliable display can be provided.

Examples of electronic devices are a television set (also referred to as a television or a television receiver), a monitor of a computer or the like, a camera such as a digital camera or a digital video camera, a digital photo frame, a mobile phone handset (also referred to as a mobile phone or a mobile phone device), a portable game machine, a portable information terminal, an audio reproducing device, a large-sized game machine such as a pachinko machine, and the like.

FIG. 12A illustrates a portable information terminal, which includes a main body 1101, a housing 1102, display portions 1103a and 1103b, and the like. The display portion 1103b is a touch panel. By touching a keyboard button 1104 displayed on the display portion 1103b, a screen can be operated, and text can be input. Needless to say, the display portion 1103a may functions as a touch panel. A liquid crystal panel or an organic light-emitting panel is fabricated by using the transistor described in Embodiment 3 as a switching element and applied to the display portion 1103a or 1103b, whereby a highly reliable portable information terminal can be provided.

The portable information terminal illustrated in FIG. 12A can have a function of displaying various kinds of data (e.g., a still image, a moving image, and a text image), a function of displaying a calendar, a date, the time, or the like on the display portion, a function of operating or editing data displayed on the display portion, a function of controlling processing by various kinds of software (programs), and the like. Further, an external connection terminal (an earphone terminal, a USB terminal, or the like), a recording medium insertion portion, or the like may be provided on the back surface or the side surface of the housing.

The portable information terminal illustrated in FIG. 12A may transmit and receive data wirelessly. Through wireless communication, desired book data or the like can be purchased and downloaded from an electronic book server.

FIG. 12B illustrates a portable music player including, in a main body 1021, a display portion 1023, a fixing portion 1022 with which the portable music player can be worn on the ear, a speaker, an operation button 1024, an external memory slot 1025, and the like. A liquid crystal panel or an organic light-emitting panel is fabricated by using the transistor described in Embodiment 3 as a switching element and applied to the display portion 1023, whereby a highly reliable portable music player can be provided.

Furthermore, when the portable music player illustrated in FIG. 12B has an antenna, a microphone function, or a wireless communication function and is used with a mobile phone, a user can talk on the phone wirelessly in a hands-free way while driving a car or the like.

FIG. 12C illustrates a mobile phone which includes two housings, a housing 1030 and a housing 1031. The housing 1031 includes a display panel 1032, a speaker 1033, a microphone 1034, a pointing device 1036, a camera lens 1037, an external connection terminal 1038, and the like. The housing 1030 is provided with a solar cell 1040 for charging the mobile phone, an external memory slot 1041, and the like. In addition, an antenna is incorporated in the housing 1031. The transistor described in Embodiment 3 is applied to the display panel 1032, whereby a highly reliable mobile phone can be provided.

Further, the display panel 1032 includes a touch panel. A plurality of operation keys 1035 which are displayed as images are indicated by dotted lines in FIG. 12C. Note that a boosting circuit by which a voltage output from the solar cell 1040 is increased so as to be sufficiently high for each circuit is also included.

For example, a power transistor used for a power supply circuit such as a boosting circuit can also be formed when the oxide semiconductor film of the transistor described in the Embodiment 3 has a thickness of greater than or equal to 2 μm and less than or equal to 50 μm.

In the display panel 1032, the direction of display is changed as appropriate depending on the application mode. Further, the mobile phone is provided with the camera lens 1037 on the same surface as the display panel 1032, and thus it can be used as a video phone. The speaker 1033 and the microphone 1034 can be used for videophone calls, recording, and playing sound, and the like as well as voice calls. Moreover, the housings 1030 and 1031 in a state where they are developed as illustrated in FIG. 12C can shift, by sliding, to a state where one is lapped over the other. Therefore, the size of the mobile phone can be reduced, which makes the mobile phone suitable for being carried around.

The external connection terminal 1038 can be connected to an AC adaptor and a variety of cables such as a USB cable, whereby charging and data communication with a personal computer or the like are possible. Further, by inserting a recording medium into the external memory slot 1041, a larger amount of data can be stored and moved.

Further, in addition to the above functions, an infrared communication function, a television reception function, or the like may be provided.

FIG. 12D illustrates an example of a television set. In a television set 1050, a display portion 1053 is incorporated in a housing 1051. Images can be displayed on the display portion 1053. Moreover, a CPU is incorporated in a stand 1055 for supporting the housing 1051. The transistor described in Embodiment 3 is applied to the display portion 1053 and the CPU, whereby the television set 1050 can be highly reliable.

The television set 1050 can be operated with an operation switch of the housing 1051 or a separate remote controller. Further, the remote controller may be provided with a display portion for displaying data output from the remote controller.

Note that the television set 1050 is provided with a receiver, a modem, and the like. With the use of the receiver, the television set 1050 can receive general TV broadcasts. Moreover, when the television set 1050 is connected to a communication network with or without wires via the modem, one-way (from a sender to a receiver) or two-way (between a sender and a receiver or between receivers) information communication can be performed.

Further, the television set 1050 is provided with an external connection terminal 1054, a storage medium recording and reproducing portion 1052, and an external memory slot. The external connection terminal 1054 can be connected to various types of cables such as a USB cable, whereby data communication with a personal computer or the like is possible. A disk storage medium is inserted into the storage medium recording and reproducing portion 1052, and reading data stored in the storage medium and writing data to the storage medium can be performed. In addition, an image, a video, or the like stored as data in an external memory 1056 inserted into the external memory slot can be displayed on the display portion 1053.

Further, in the case where the off-state leakage current of the transistor described in Embodiment 3 is extremely small, when the transistor is applied to the external memory 1056 or the CPU, the television set 1050 can have high reliability and sufficiently reduced power consumption.

The methods and structures described in this embodiment can be combined as appropriate with any of the methods and structures described in the other embodiments.

This application is based on Japanese Patent Application serial No. 2012-178261 filed with the Japan Patent Office on Aug. 10, 2012, the entire contents of which are hereby incorporated by reference.

What is claimed is:

1. A method for forming an oxide semiconductor film, comprising the steps of:
making an ion collide with a sputtering target including a polycrystalline oxide containing crystal grains to separate parts of the crystal grains and obtain flat plate-like sputtered particles; and
depositing the flat plate-like sputtered particles on a substrate having an insulating surface, which is heated at a temperature higher than 400° C. and lower than or equal to 500° C. to form an oxide semiconductor film including a crystal part over the substrate,
wherein a diameter of a plane of the sputtered particle which is parallel to an a-b plane of a crystal is greater than or equal to 3 nm and less than or equal to 10 nm.

2. The method for forming an oxide semiconductor film according to claim 1,
wherein the polycrystalline oxide comprises indium, zinc, and a metal other than indium and zinc.

3. The method for forming an oxide semiconductor film according to claim 2,
wherein the metal other than indium and zinc is gallium.

4. The method for forming an oxide semiconductor film according to claim 1,
wherein c-axes of crystals of the deposited sputtered particles are aligned in a direction perpendicular to a deposition surface of the substrate.

5. The method for forming an oxide semiconductor film according to claim 1,
wherein the crystal grains have cleavage planes, and
wherein the crystal grains are separated from the sputtering target along the cleavage planes.

6. The method for forming an oxide semiconductor film according to claim 1,
wherein the sputtered particles are positively charged during the deposition.

7. A method for forming an oxide semiconductor film, comprising the steps of:
making an ion collide with a sputtering target including a polycrystalline oxide containing crystal grains to separate parts of the crystal grains and obtain hexagonal prism sputtered particles; and
depositing the hexagonal prism sputtered particles on a substrate having an insulating surface, which is heated at a temperature higher than 400° C. and lower than or equal to 500° C., to form an oxide semiconductor film including a crystal part over the substrate.

8. The method for forming an oxide semiconductor film, according to claim 7,
wherein a hexagonal plane of the hexagonal prism sputtered particles is parallel to an a-b plane of a crystal, and
wherein a direction perpendicular to the hexagonal plane is a c-axis direction of the crystal.

9. The method for forming an oxide semiconductor film, according to claim 8,
wherein the sputtered particles are deposited in a direction such that the hexagonal plane is parallel to a deposition surface of the substrate.

10. The method for forming an oxide semiconductor film, according to claim 8,
wherein a length of a diagonal line of the hexagonal plane is greater than or equal to 3 nm and less than or equal to 10 nm.

11. The method for forming an oxide semiconductor film, according to claim 7,
wherein the polycrystalline oxide comprises indium, zinc, and a metal other than indium and zinc.

12. The method for forming an oxide semiconductor film, according to claim 11,
wherein the metal other than indium and zinc is gallium.

13. The method for forming an oxide semiconductor film, according to claim 7,
wherein the crystal grains have cleavage planes, and
wherein the crystal grains are separated from the sputtering target along the cleavage planes.

14. The method for forming an oxide semiconductor film, according to claim 7,
wherein the sputtered particles are positively charged during the deposition.

15. The method for forming an oxide semiconductor film, according to claim 7,
wherein the oxide semiconductor film is formed in an atmosphere containing an oxygen gas.

16. A method for forming an oxide semiconductor film, comprising the steps of:
making an ion collide with a sputtering target including a polycrystalline oxide containing crystal grains to separate parts of the crystal grains and obtain triangular prism sputtered particles; and
depositing the triangular prism sputtered particles on a substrate having an insulating surface, which is heated at a temperature higher than 400° C. and lower than or equal to 500° C., to form an oxide semiconductor film including a crystal part over the substrate.

17. The method for forming an oxide semiconductor film, according to claim 16,
wherein the polycrystalline oxide comprises indium, zinc, and a metal other than indium and zinc.

18. The method for forming an oxide semiconductor film, according to claim 17,
wherein the metal other than indium and zinc is gallium.

19. The method for forming an oxide semiconductor film, according to claim 16,
wherein c-axes of crystals of the deposited sputtered particles are aligned in a direction perpendicular to a deposition surface of the substrate.

20. The method for forming an oxide semiconductor film, according to claim 16,
wherein the crystal grains have cleavage planes, and
wherein the crystal grains are separated from the sputtering target along the cleavage planes.
